(19) United States
(12) Patent Application Publication
(10) Pub. No.: US 2024/0265941 A1
(43) Pub. Date: Aug. 8, 2024

(54) IMPROVEMENTS IN OPTICAL DATA STORAGE

(71) Applicant: UNIVERSITY OF SOUTH AUSTRALIA, Adelaide (AU)

(72) Inventors: Nicolas Noel RIESEN, Adelaide (AU); Hans Albert RIESEN, Adelaide (AU)

(21) Appl. No.: 18/568,250

(22) PCT Filed: Jun. 8, 2022
(86) PCT No.: PCT/AU2022/050563

§ 371 Date: Dec. 7, 2023

(30) Foreign Application Priority Data
Jun. 8, 2021 (AU) 2021901706

(51) Int. Cl. G11B 7/0045; G11B 7/005; G11B 7/2533

(52) U.S. Cl. CPC G11B 7/00455; G11B 7/0052; G11B 7/2533

(57) ABSTRACT

A data storage medium for storing digital data. The medium includes a mixture of different nano-sized materials, each of the nano-sized materials having a respective optical transition profile characterizing an optical transition of the nano-sized material and covering a respective wavelength range, wherein a combined optical transition profile of the mixture covers an extended wavelength range as compared to the respective wavelength ranges of the respective optical transition profiles of the different nano-sized materials, and wherein one or more of the different nano-sized materials is photo-reactive to selectively vary a respective absorption/emission band upon irradiation to encode digital data in the combined optical transition profile of the mixture.

### PRIORITY DOCUMENTS

The present application claims priority from Australian Provisional Patent Application No. 2021901706 titled “IMPROVEMENTS IN OPTICAL DATA STORAGE” and filed on 8 Jun. 2021, the content of which is incorporated by reference in its entirety.

### INCORPORATION BY REFERENCE

The following publication is referred to in the present application and its entire contents are incorporated by reference:

Xiang-lei Wang, Zhi-qiang Liu, Marion A. Stevens-Kalceff, and Hans Riesen, “Mechanochemical Preparation of Nanocrystalline BaFCl Doped with Samarium in the 2+ Oxidation State”, Inorganic Chemistry, 2014, 53 (17), 8839-8841.

### TECHNICAL FIELD

The present disclosure relates to the storage of data. In a particular form, the present disclosure relates to a high density/high capacity optical based data storage medium.

### BACKGROUND

In recent years worldwide data generation has grown at least 3-times faster than data storage capacities. This rapid growth has been driven by a massive increase in the use of the internet, social media and cloud computing. Traditional data storage technologies based on magnetic (eg, hard disk drives or tape) or solid-state (eg, solid state drives) have failed to address the growth in data storage demand.

Optical based storage arrangements have been one approach to the large scale storage of data and include implementations such as write-once-read-many times (WORM) storage media involving permanent ablation of a readable surface by a dye layer and rewritable implementations adopting the reversible change between amorphous and crystalline phases in thin metal, alloy or semiconductor films by laser heating. Optical data storage has some significant benefits over traditional hard drive technologies in terms of longer lifetime and significantly reduced operational energy requirements. Optical data storage could also offer much higher write and read speeds compared with commonly used magnetic tape and it is an attractive alternative to SSD technologies which can be prohibitively expensive for big data storage applications.

However, these optical based storage arrangements, including disc based arrangements such as CDs, DVDs and BDs, are ultimately restricted by the diffraction limited read/write area A of the laser as determined by the numerical aperture (NA) of the focussing lens and the wavelength of the laser that is employed. As an example, standard Blu-Ray™ arrangements with a typical NA of 0.85 and a 405 nm laser can only achieve a surface data density of approximately 2 Gb/cm² resulting in a typical limit of around 25 GB per disc per layer. With requirements of petabyte to exabyte storage capacities, standard 25 GB (or 50 GB dual-layer) optical discs are not a viable solution for the large-scale storage demands of the future.

Against this background, it would be desirable to provide alternative optical based arrangements for data storage capable of increasing digital data storage capacities and/or to provide an alternative to current data storage methodologies.

### SUMMARY

In a first aspect, the present disclosure provides a data storage medium for storing digital data comprising:
a mixture of different nano-sized materials, each of the nano-sized materials having a respective optical transition profile characterizing an optical transition of the nano-sized material and covering a respective wavelength range, wherein a combined optical transition profile of the mixture covers an extended wavelength range as compared to the respective wavelength ranges of the respective optical transition profiles of the different nano-sized materials, and wherein one or more of the different nano-sized materials is photo-reactive to selectively vary a respective absorption/emission band upon irradiation to encode digital data in the combined optical transition profile of the mixture.

In another form, the respective absorption/emission band is frequency selectively bleached to form a spectral hole in the combined optical transition profile to encode digital data.

In another form, the spectral hole in the combined optical transition profile is configured to have a predetermined depth level, the predetermined depth level selected from a plurality of depth levels to encode digital data in the spectral hole of the combined optical transition profile.

In another form, the respective wavelength ranges of the respective optical transition profiles of the different nano-sized materials have substantially the same width.

In another form, respective peak wavelengths of the respective optical transition profiles of the different nano-sized materials are substantially equally spaced with respect to each other.

In another form, the combined optical transition profile comprises a substantially flat portion over the extended wavelength range.

In another form, the mixture is distributed in a substantially two-dimensional (2D) configuration.

In another form, the mixture is distributed in a substantially three-dimensional (3D) configuration.

In another form, the different nano-sized materials comprise different BaₓSr_{y}Ca_{z}FClᵣBrₛIₜ:Sm²⁺ nanocrystal materials where the values of x, y, z, r, s and t are selected from 0 to 1 and subject to the constraints that x+y+z=1 and r+s+t=1.

In another form, the different nano-sized materials comprise different Ba₁₋ₓSrₓFCl: Sm²⁺ nanocrystal materials where x is selected from 0 to 1.

In another form, the data storage medium is operable to store and read digital data at cryogenic temperatures.

In another form, the data storage medium is operable to store and read digital data at substantially non-cryogenic temperatures.

In another form, the data storage medium is operable to store and read digital data at substantially room temperature.

In a second aspect, the present disclosure provides a method for storing digital data, comprising:
providing the data storage medium of the first aspect; and
irradiating the data storage medium in accordance with the digital data to selectively vary the respective absorption/emission band to encode the digital data.

In a third aspect, the present disclosure provides a method for reading stored digital data, comprising:
providing the data storage medium of the first aspect; and
determining whether the respective absorption/emission band has been selectively varied to decode the digital data.

In another form, determining whether the respective absorption/emission band has been selectively varied comprises measuring a reflection profile of the data storage medium.

In another form, determining whether the respective absorption/emission band has been selectively varied comprises measuring an absorption profile of the data storage medium.

In another form, determining whether the respective absorption/emission band has been selectively varied comprises measuring an emission profile of the data storage medium.

### BRIEF DESCRIPTION OF DRAWINGS

Embodiments of the present disclosure will be discussed with reference to the accompanying drawings wherein:

FIG. 1 is a figurative view of a data storage medium comprising a mixture of different nano-sized materials each having a respective optical transition profile in accordance with an illustrative embodiment;

FIG. 2 is a plot of the combined optical transition profile of the data storage medium illustrated in FIG. 1 also showing the respective individual optical transition profiles of the different nano-sized materials forming the mixture;

FIG. 3 is a plot of an optical transition profile of a nano-sized material illustrating the individual homogeneous line width components in accordance with an illustrative embodiment;

FIG. 4 is a plot of a modified optical transition profile corresponding to the optical transition profile illustrated in FIG. 3 following frequency selectively bleaching of an absorption/emission band upon irradiation in accordance with an illustrative embodiment;

FIG. 5 is a plot of the combined optical transition profile illustrated in FIG. 2 following irradiation showing the spectral holes or gaps used to encode digital information in the data storage medium in accordance with an illustrative embodiment;

FIG. 6 is a plot of the combined optical transition profile illustrated in FIG. 2 following irradiation showing spectral holes that have been configured to have various predetermined depth levels selected from a number of set depth levels in order to encode digital information in the spectral hole in accordance with an illustrative embodiment;

FIG. 7 is a figurative view of a read/write apparatus for reading and/or writing digital data with respect to a data storage medium in accordance with an illustrative embodiment;

FIG. 8 is an enlarged view of the irradiation region where the beam of the read/write apparatus illustrated in FIG. 7 is incident on the data storage medium in accordance with an illustrative embodiment;

FIG. 9 is a plot showing the variation of room temperature peak energy and full width half maximum of the Sm^{2+ 5}D₀→⁷F₀ optical transition in Ba₁₋ₓSrₓFCl as a function of x in accordance with an illustrative embodiment;

FIG. 10 is a plot of the respective optical transition profiles of the Sm²⁺⁵D₀→7F₀ luminescence line for different Ba₁₋ₓSrₓFCl:Sm²⁺ nanocrystal materials where x=0, 0.4, 0,6, 0.8 and 1. and also the combined optical transition profile of a mixture comprising the x=0.4, 0.6 and 0.8 nanocrystal materials in accordance with an illustrative embodiment;

FIG. 11 is a plot of two combined optical transition profiles 1120, 1150 of the mixture of different Ba₁₋ₓSrₓFCl:Sm²⁺ nanocrystal materials following hole burning to selectively vary or modify an absorption/emission band to form a spectral hole in the combined optical transition profile to encode digital data in accordance with an illustrative embodiment;

FIG. 12 is a plot of the combined optical transition profile of a data storage medium comprising different Ba₁₋ₓSrₓFCl: Sm²⁺ nanocrystal materials cooled to 175 K and showing multiple spectral holes in accordance with an illustrative embodiment;

FIG. 13 is a plot of a spectral hole in the combined optical transition profile of a data storage medium comprising different Ba₁₋ₓSrₓFCl: Sm²⁺ nanocrystal materials cooled to 30 K;

FIG. 14 is a flowchart of a method for storing digital information in a data storage medium in accordance with an illustrative embodiment; and

FIG. 15 is a flowchart of a method for reading digital information from a data storage medium in accordance with an illustrative embodiment.

In the following description, like reference characters designate like or corresponding parts throughout the figures.

### DESCRIPTION OF EMBODIMENTS

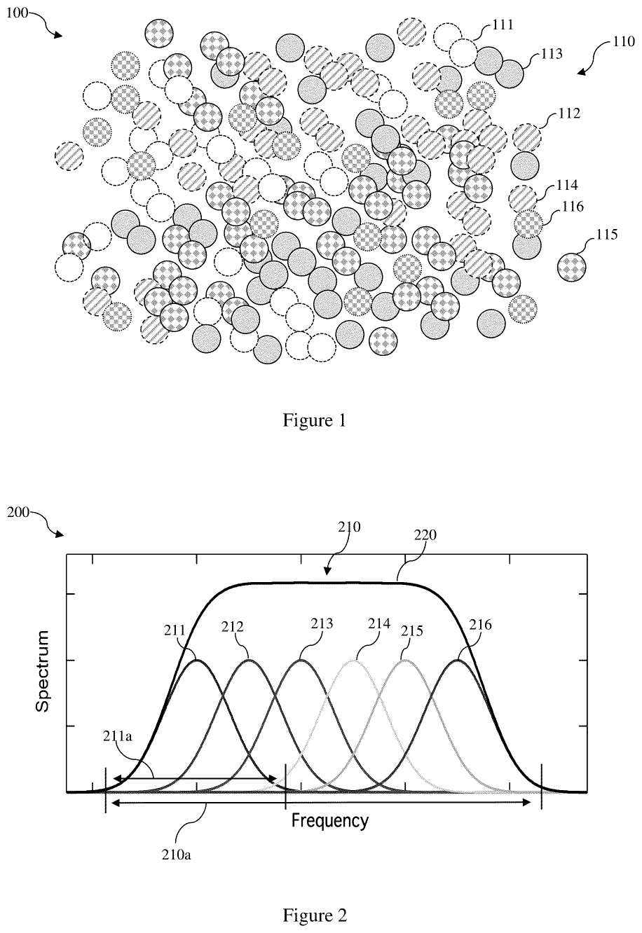

Referring now to FIG. 1, there is shown a figurative view of a data storage medium 100 comprising a mixture 110 of different nano-sized materials according to an illustrative embodiment. In this example, the mixture 110 comprises six different nano-sized materials 111, 112, 113, 114, 115, 116 dispersed or distributed in a substantially two-dimensional (2D) configuration. As will be described below, the data storage medium may be configured in a 2D configuration or in other embodiments the mixture may be distributed or dispersed throughout a volume in a three-dimensional (3D) configuration. In other embodiments, the combination 100 may comprise as few as two different nano-sized materials.

Throughout this specification the term “nano-sized material” is defined to mean a particle, compound, composition, structure or substance having a size or extent of less than 1 μm. In different embodiments, an individual nano-sized material may have a size in one or more of the following size ranges including, but not limited to, less than 25 nm, 25 nm-50 nm, 50 nm-75 nm, 75 nm-100 nm, 100 nm-125 nm, 125 nm-150 nm, 150 nm-175 nm, 175 nm-200 nm, 200 nm-225 nm, 225 nm-250 nm, 250 nm-300 nm, 300 nm-350 nm, 350 nm-400 nm, 400 nm-450 nm, 450 nm-500 nm, 500 nm-550 nm, 550 nm-600 nm, 600 nm-700 nm, 700 nm-800 nm, 800 nm-900 nm, and 900 nm-1000 nm.

In one example, the mixture may comprise different nano-sized materials all lying within the same size range, eg, 25 nm-50 nm. In another example, the different nano-sized materials may lie within different size ranges with respect to each other, eg, some of the different nano-sized material may be in the size range 25 nm-50 nm and others in the size range 100 nm-125 nm with the mixture together extending over a size range of 100 nm.

Referring now to FIG. 2, there is shown a plot 200 of the respective optical transition profiles 211, 212, 213, 214, 215, 216 of each of the nano-sized materials 111, 112, 113, 114, 115, 116 where an individual optical transition profile characterises an optical transition of the given nano-sized material. In this example, the optical transition profile could be either the emission or absorbance spectrum related to a particular optical transition of the nano-sized material. Also shown in FIG. 2 is the combined optical transition profile 210 representing, in this example, the combined emission/absorbance spectrum of mixture 110. As can be seen, the combined optical transition profile 210 covers an extended wavelength range 210a as compared to the respective wavelength range of an optical transition profile of any one of the individual nano-sized materials (eg, wavelength range 211a for optical transition profile 211 for nano-sized material 111).

In this example, one or more of the different nano-sized materials is photo-reactive to selectively vary or bleach a respective absorption/emission band upon irradiation at the band wavelength to encode digital data in the combined optical transition profile 210 of mixture 110.

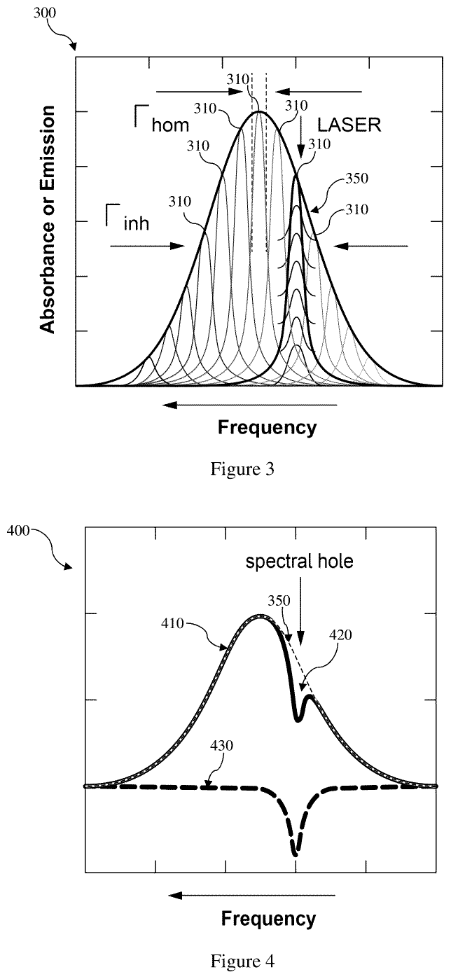

Referring now to FIG. 3, there is shown a plot 300 of the optical transition profile 350 of an individual nano-sized material depicting the individual homogeneous optical transition components 310 which themselves have their own linewidths, Thom, arising principally from thermal broadening, ie, as temperature increases Thom will increase. As can be seen, the individual homogeneous linewidth components 310 are themselves spread or shifted over a wavelength range for a particular nano-sized material due to local environmental variability of absorption/emission or optical centre sites within the nano-sized material to form an inhomogeneous distribution for a given nano-sized material having optical transition profile 350 which may be characterised by inhomogeneous linewidth Γᵢₙₕ.

As an example, this variability could be caused by imperfection in the crystal lattice for a crystal based material. This may be caused by different bond lengths, proximity to impurity centres and isotope distributions resulting in an overall normal distribution over frequency for a given optical transition for the nano-sized material characterised by an inhomogeneous linewidth Γᵢₙₕ.

Referring now to FIG. 4, there is shown a plot 400 of the modified optical transition profile 410 corresponding to the optical transition profile 350 illustrated in FIG. 3, following frequency selectively bleaching or varying a respective absorption/emission band upon irradiation to form a gap or spectral hole 420 in the optical transition profile. The delta optical transition profile 430 is also plotted showing the change between the original optical transition profile 350 and the modified optical transition profile 410. In principle, the presence or absence of a spectral hole or gap may then be used to encode binary 0s or 1s at a particular wavelength.

As will be appreciated, the number of holes that may be “burnt” or “bleached” into an optical transition profile of a given compound or material having an inhomogeneous linewidth is given by the ratio of the inhomogeneous to homogeneous linewidth (ie, Γᵢₙₕ/Γₕₒₘ) which may be used as a figure-of-merit to characterise an optical transition profile. This ratio can be up to 10⁸ at very low temperature and hence theoretically large data storage densities are potentially possible albeit at impractical liquid helium temperatures.

In most cases the homogeneous linewidth for a given material will be dominant at room temperature due to the rapid dynamic broadening of optical transitions which occur due to interactions with phonons. Natural (homogeneous) optical linewidths are governed by a range of dynamical processes such as two-phonon Raman scattering, direct one-phonon relaxation, etc, leading to dephasing of the wavefunctions. These processes are strongly temperature dependent becoming much more important at high temperatures, leading to relatively broad homogeneous linewidths at room temperature. This then results in large homogeneous linewidths that are typically wider than the inhomogeneous linewidth of the material at room temperature as a result preventing discernible individual spectral holes from being formed in the optical transition profile for most materials.

Referring back to FIG. 2, in this illustrative embodiment, the different nano-sized materials 111, 112, 113, 114, 115, 116 each have respective peaks in their optical transition profiles 210 that are offset from each other, and in this embodiment, the combined optical transition profile 210 comprises a substantially flat portion 220 over the extended wavelength range forming a “top hat” profile. As would be appreciated, the combined optical transition profile 210 may be dependent on factors including, but not limited to, the concentration of any individual nano-sized material in the mixture, the size of the nano-sized material and the optical transition efficiency of the nano-sized material.

As such, the combined optical transition profile 210 may be “designed” to have a predetermined profile having at least the characteristic that the wavelength range covered by the combined optical transition profile is broader or broadened as compared to that of the optical transition profiles of individual nano-sized material forming the mixture. In one example, the optical transition profiles of each of the nano-sized materials have substantially the same width and their respective peak wavelengths are equally spaced with respect to each other as shown in FIG. 2. In other embodiments, the optical transition profiles may be substantially different in form and different wavelength ranges with respect to each other. As would be appreciated, the requirements for data storage will determine the characteristics of the combined optical transition profile.

As would be appreciated, the combined optical transition profile 210 of the mixture of different nano-sized materials in accordance with the present disclosure has an effective combined inhomogeneous linewidth that exceeds any individual inhomogeneous line width of an individual nano-sized material. In this embodiment, one or more of nano-sized materials 111, 112, 113, 114, 115, 116 are chosen to be selectively photo-reactive so that on irradiation at the band wavelength, the emission/absorption band corresponding to that wavelength will be varied or bleached in effect producing a spectral hole or “gap” in the combined optical transition profile at this frequency.

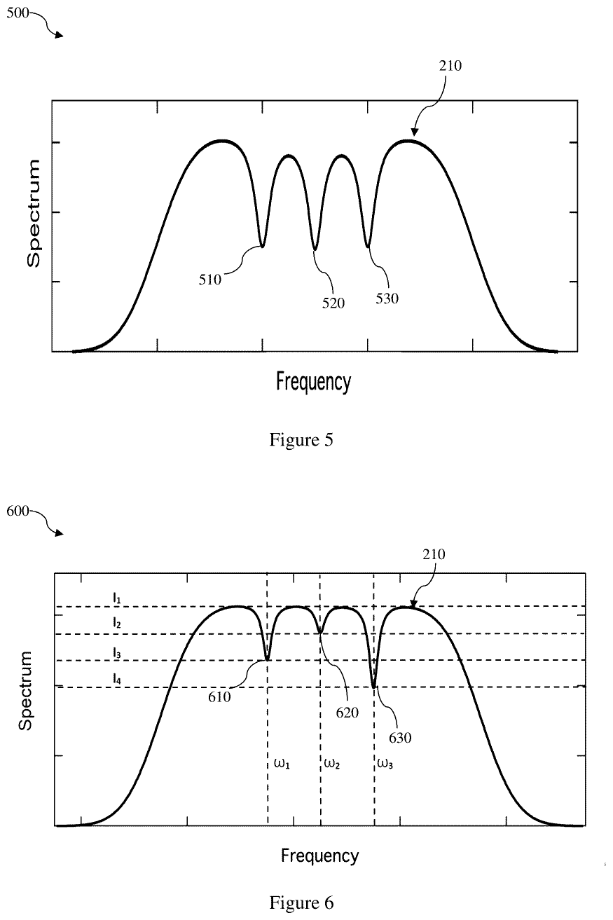

Referring now to FIG. 5, there is shown a plot 500 of the combined optical transition profile 210 following irradiation or hole-burning of the data storage medium 100 to selectively vary or bleach a number of absorption bands to form spectral holes or gaps 510, 520 and 430 where there has been a reduction in absorption/emission which may be used to encode digital data in the combined optical transition profile 210 on the basis that the absence/presence of gap at a particular wavelength location on the combined optical transition profile indicates a “0” or “1” for a bit corresponding to that wavelength location.

In one example, the operable wavelengths where spectral holes may be formed lies substantially within the range of 400 nm-800 nm range, however, any wavelength is possible but as would be appreciated the diffraction limited spot becomes much smaller with decreasing wavelength. As such, any typical diffraction limited irradiation (or read) process will interact with large numbers of the different nano-sized materials and so it will be the combined optical transition profile of these different nano-sized materials that is “seen” by any irradiation or probe beam on interacting with a diffraction limited region of the data storage medium.

Referring now to FIG. 6, there is shown a plot 600 of the combined optical transition profile 210 following irradiation of the data storage medium 100 to selectively bleach or vary a number of absorption/emission bands to form spectral holes 610, 620 and 630. In this case, and recognising that data storage medium 100 comprises a combination of different nano-sized materials that are distributed over a physical region defined by the irradiation process, the degree to which all of an individual photo-luminescent material present in the mixture is subject to a bleaching of the respective absorption band will be approximately dependent on the degree or burn fluence of irradiation at the relevant wavelength by modifying the duration and/or intensity of irradiation at the relevant wavelength.

In this manner, the depth level of a given spectral hole or gap in the combined optical transition profile 210 may be selected from a number of set depth levels by choosing the degree of irradiation of data storage medium 100 in order to store additional digital information in a respective spectral hole.

This is shown in plot 600 where each of the spectral gaps 610, 620, 630 are selected from four depths, ie, where spectral gap 610 corresponds to depth I₃, spectral gap 620 corresponds to depth I₂ and spectral gap 630 corresponds to depth I₄. Combined with the state where there is no spectral gap at a selected frequency or wavelength, ie depth I₁, this corresponds to four depth levels or two bits of encoding in this example for each spectral hole 610, 620, 630.

Although in FIG. 6, there are multiple spectral holes at multiple different frequencies (at multiple different depth levels) it would be appreciated that the data storage medium may be configured to have a single spectral hole having multiple depth levels. In general, if N is the number of depth levels then the number of bits that can be encoded per spectral hole in the case of binary encoding will be log₂(N), eg 32 levels would be 5 bits/hole. In various embodiments, the number of depth levels per spectral hole may be selected to be 2, 4, 8, 16, 32 or greater than 32.

As would be appreciated, there are other schemes for encoding digital data apart from the rudimentary binary encoding referred to above which may be implemented in accordance with the present disclosure especially appreciating that a spectral hole at a given wavelength location may be used to encode multiple bits of information.

The nano-sized materials that form the mixture may be any suitable material exhibiting the required optical transition characteristics, ie, having an isolated optical transition where a peak in the individual optical transition profile differs across the different nano-sized materials and further where one or more of the nano-sized materials have the characteristic that irradiation by specific wavelengths can result in an absorption/emission band corresponding to that wavelength being varied effectively leaving a spectral hole at the respective wavelength.

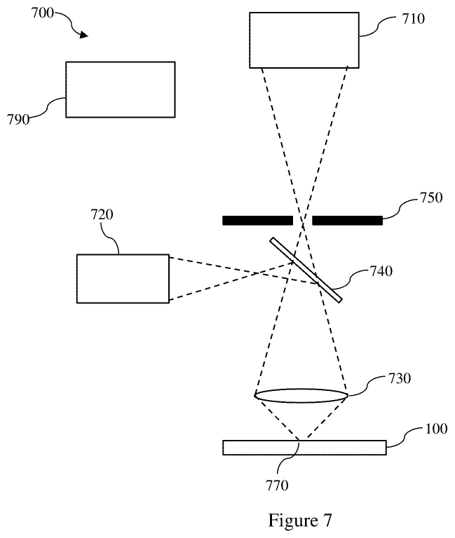

Referring now to FIG. 7, there is shown a figurative view of an example read/write apparatus 700 for reading and/or writing digital data with respect to data storage medium 100 according to an illustrative embodiment. In this example, read/write apparatus 700 has a confocal configuration.

Read/write apparatus 700 comprises in this example an intensity detector 710, a configurable wavelength radiation source 720, a focusing arrangement comprising in this embodiment an objective lens 730 for focusing radiation onto, or into, an irradiation region 770 of the digital storage medium 100 and a beam splitter 740 for introducing the radiation into the optical path of the apparatus 700 and a pinhole arrangement 750.

In this example, detector 710 may comprise any suitable detector for measuring photon intensity in the wavelength range of interest such as by the use of one or more photomultiplier tubes or photodiodes including avalanche photodiodes, CCDs, CMOS or any other light sensitive device, or in another example using silicon photomultiplier (SiPM) detectors. In another example, an optical fibre arrangement may be used to collect or deliver light.

Configurable wavelength radiation source 720 may be any suitable optical arrangement capable of emitting an irradiation or probe beam at a selected wavelength and in one embodiment at a selectable intensity or duration for a given wavelength to vary the depth level of spectral holes being formed in the combined optical transition profile as referred to above. In one example, radiation source 720 may comprise multiple discrete lasers or LEDs operating at the relevant wavelengths. In other embodiments, radiation source 720 may be based on a single-frequency light source such as a tuneable laser. In another embodiment, the light of LEDs may be filtered or narrowed by the use of narrow bandpass filters or wavelength dispersive element to provide radiation at the required wavelengths.

In this example confocal configuration, the path length from wavelength radiation source 720 to the data storage medium 100 is equivalent to the path length from the data storage medium 100 to the detector 710. Read/write apparatus 700 also comprises a data processor 790 for controlling the writing process to write digital information onto digital storage medium 100 and processing the emission/absorption readings from detector 710 to decode any digital information stored in digital storage medium 100. In one example implementation, read/write apparatus 700 may be configured to measure a reflection profile from the data storage medium. In another embodiment, read/write apparatus 700 may be configured to measure an absorption profile of the data storage medium. In yet another embodiment, read/write apparatus 700 may be configured to measure an emission profile of the data storage medium. As would also be appreciated, read/write apparatus 700 may be configured as separate apparatus directed to read or writing individually.

As the read/write apparatus 700 is only sampling an irradiation region 770 at any instance defined by the diffraction limited spot size of the irradiation/probe beam, in order to read/write different regions the digital storage medium 100 must be translated with respect to the location of irradiation region 770. This may be achieved by either moving the read/write apparatus 700 or digital storage medium 100 or both with respect to each other. In another example, the irradiation region 770 may be moveable with respect to the read/write apparatus so that the probe beam may adopt a scanning pattern. As would be appreciated, where digital storage medium 100 has a 3D configuration this will also require translation in depth as well as within a plane of digital storage medium.

In one example, the digital storage medium 100 is formed as a 2D disc and the disc is rotated to present a different irradiation region 700 to the read/write apparatus. As would be appreciated, as the digital storage medium is being read or written at different wavelengths, different read/write schemes may elect to read/write the entire digital storage medium 100 at a first wavelength and then at a second wavelength or select a “track” of the digital storage medium that is read/written at a first wavelength and then a second wavelength before moving onto the next track.

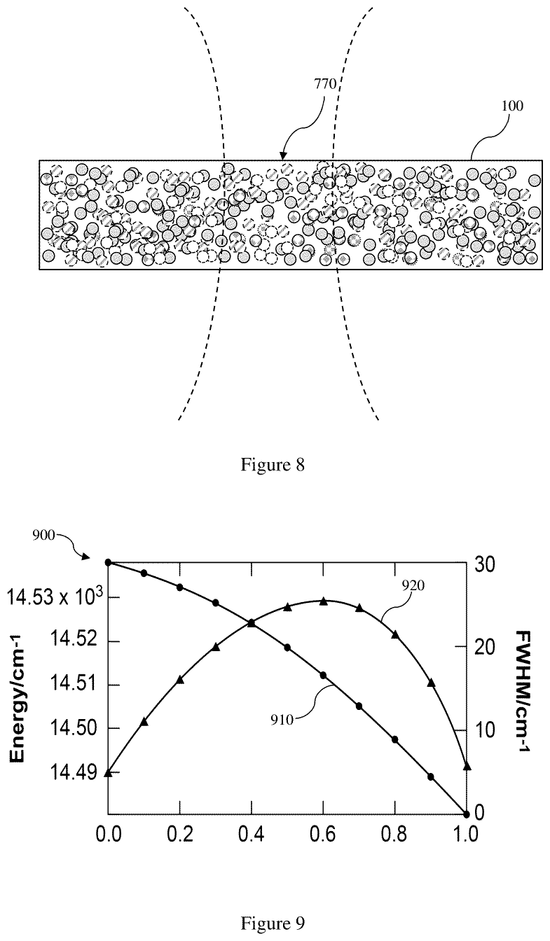

Referring now to FIG. 8, there is shown an enlarged view of the irradiation region 770 where the beam of read/write apparatus is incident on digital storage medium 100 according to an illustrative embodiment. As can be seen, the diffraction limited focused beam of the read/write apparatus will sample a mixture comprising multiple instances of the different nano-sized materials by virtue of their size relative to the focused beam and as such the optical transmission profile determined by the probe beam will be the combined optical transition profile comprising the respective optical transition profiles of the different nano-sized materials “seen” by the probe beam. For the purposes of illustration, only tens of different nano-sized materials are shown being sampled by the probe beam but as would be appreciated, there would be hundreds, thousands or even more different nano-sized materials that would be seen in any diffraction limited focused probe beam.

In this example, data storage medium 100 is a thin film where even though the film has some thickness the mixture of different nano-sized materials is distributed in a substantially planar 2D-configuration so that the irradiation region is a planar region (eg, a “pixel”) located on the surface of data storage medium 100. In one example, the thin film is deposited on a suitable substrate. The data storage medium may be deposited in a homogeneous or patterned arrangement as required. Additionally, the substrate may be flexible or substantially rigid and the data storage medium 100 be deposited on one or both sides of the substrate.

This may be compared with where the data storage medium has a substantial thickness and the mixture of different nano-sized materials is distributed in substantially three-dimensional configurations in which case the irradiation region may be shifted to sample an irradiation region at a selected depth or discrete layer (eg, a “voxel”) within the data storage medium by virtue of focusing the beam at this selected depth or discrete layer. 3D configurations include, but are not limited to, multiple layer implementations deposited on a substrate in a homogeneous or patterned manner or in another medium, eg, formed in polymer, glass, sol-gel, soft glass or suitable material and could be formed into any geometric volume such as a cube, cylinder, or sphere. In addition, the nano-sized materials could be uniformly dispersed within the volume, or dispersed in accordance with a pattern or alternatively randomly distributed through the volume.

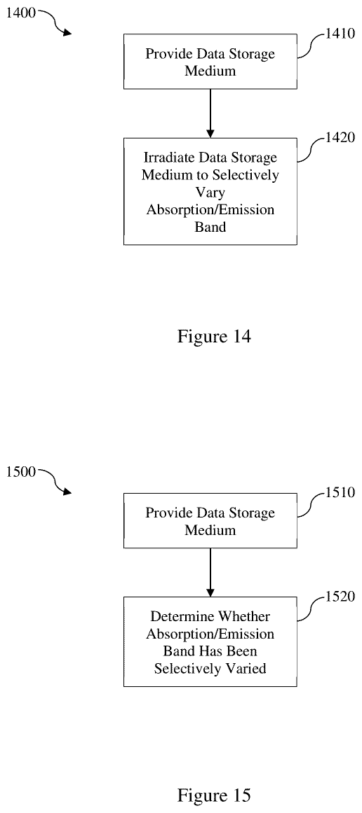

Referring now to FIG. 14, there is shown a flowchart 1400 of a method for storing digital information according to an illustrative embodiment. At step 1410, a data storage medium 100 is provided in accordance with the present disclosure. At step 1420, the data storage medium is then irradiated in accordance with the digital data to selectively vary or bleach one or more respective absorption/emission bands to encode the digital data by in one example forming spectral holes, which may be at varying depth levels, in the combined optical transition profile at selected wavelengths.

Referring now to FIG. 15, there is shown a flowchart 1500 of a method for reading stored digital data according to an illustrative embodiment. At step 1510, a data storage medium 100 is provided in accordance with the present disclosure. At step 1520, the data storage medium is then probed to determine whether respective absorption/emission bands have been selectively varied/bleached to form spectral holes in the combined optical transition profile at selected wavelengths to decode any digital data that has been encoded on data storage medium 100 noting that the absence of a spectral hole at a selected wavelength may form part of the encoding. In one example, the depth of any spectral hole may be probed to determine whether digital information has been encoded in the spectral hole as a result of the measured depth corresponding to a selected depth level. In one example, a nano-sized material such as a nano-crystal material may be used. In one embodiment, the mixture of different nano-sized materials comprises different nanocrystal materials. In one example, the different nano-crystal materials are 30-nm matlockite nanocrystals that in one embodiment comprise Ba₁₋ₓSrₓFCl:Sm²⁺ nanocrystal materials that have been configured to have different optical transition profiles characterised by each profile having a different peak absorbance/emission wavelength by adjusting the mol-fraction x.

In one example, the nano-crystal materials are prepared by a mechanochemical method such as by ball milling where constituent compounds such as BaCl₂ and BaF₂ are mixed or milled together under an argon (or another inert gas) atmosphere and where the Sm²⁺ may be incorporated directly by using divalent Sm (as in SmI₂) in the ball milling process. In this case the ball milling has to be undertaken with fully dried reagents and under an inert gas such as argon. Alternatively, in another example, the 2+ oxidation state may be achieved by exposing the formed materials to ionising radiation such as X-rays to reduce the incorporated Sm³⁺ to Sm²⁺.

Techniques for forming nanocrystal materials in accordance with the present disclosure are discussed in the paper by Xiang-lei Wang, Zhi-qiang Liu, Marion A. Stevens-Kalceff, and Hans Riesen titled “Mechanochemical Preparation of Nanocrystalline BaFCl Doped with Samarium in the 2+ Oxidation State” (Inorganic Chemistry, 2014, 53 (17), 8839-8841), whose entire disclosure is incorporated by reference.

TABLE 1
Table of Lattice Parameters and Average Crystallite
Sizes for example Ba₁₋ₓSrₓFCl synthesis.

| x | a (Angstroms) | c (Angstroms) | size (nm) |
|---|---|---|---|
| 0 | 4.4022(8) | 7.2466(4) | 37 |
| 0.1 | 4.3878(4) | 7.2289(9) | 52 |
| 0.2 | 4.3682(4) | 7.2095(9) | 41 |
| 0.3 | 4.3455(5) | 7.189(1) | 36 |
| 0.4 | 4.3122(6) | 7.155(1) | 27 |
| 0.5 | 4.2979(7) | 7.144(2) | 22 |
| 0.6 | 4.2502(6) | 7.094(1) | 24 |
| 0.7 | 4.2181(5) | 7.068(1) | 29 |
| 0.8 | 4.1893(6) | 7.0388(9) | 30 |
| 0.9 | 4.1591(5) | 7.009(9) | 37 |
| 1.0 | 4.1298(5) | 6.9781(7) | 31 |

Table 1 summarises the relevant lattice parameters and the average crystallite size for the different Ba₁₋ₓSrₓFCl: Sm²⁺ nanocrystal materials for x ranging from 0 to 1 in accordance with an illustrative embodiment.

In this illustrative embodiment, the optical transition profile for each of the nanocrystal materials is based on the divalent Sm²⁺⁵D₀→⁷F₀ optical transition which shifts non-linearly both with mol-fraction x as well as the unit cell length a and c.

Referring now to FIG. 9, there is shown a plot 900 of the room temperature peak energy 910 and full width at half maximum (FWHM) 920 of the Sm²⁺⁵D₀→⁷F₀ optical transition in Ba₁₋ₓSrₓFCl: Sm²⁺ as a function of mol-fraction x according to an illustrative embodiment. In this example, the divalent samarium was generated from Sm³⁺ by exposure of the nanocrystal material to a dose of 5 Gray 40 kV X-rays. As can be seen, the peak energy 910 shifts non-linearly with x to lower energies. This is consistent with the redshift of luminescence upon cooling of the system.

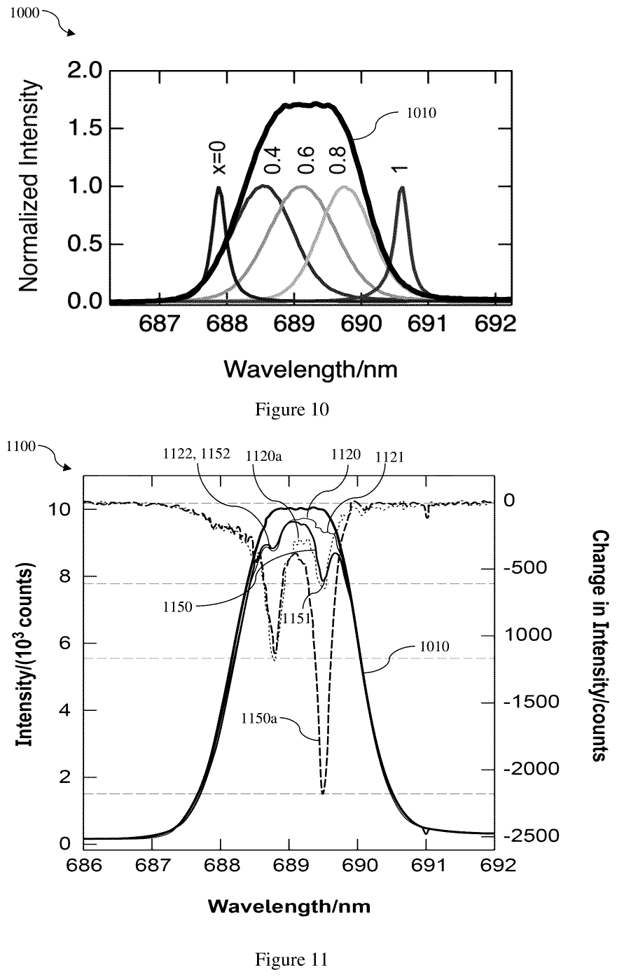

Referring now to FIG. 10, there is shown a plot 1000 of the optical transition profile of the Sm²⁺⁵D₀→⁷F₀ luminescence line for different Ba₁₋ₓSrₓFCl: Sm²⁺ nanocrystal materials where x=0, 0.4, 0.6, 0.8 and 1 as indicated according to an illustrative embodiment. Also shown is the combined optical transition profile 1010 for a mixture comprising the x=0.4, 0.6 and 0.8 nanocrystal materials showing in this example a flat top profile that is better than 1%. For these measurements the luminescence spectra were excited by a 430 nm LED light source and measured by a monochromator equipped with a CCD camera.

Referring now to FIG. 11, there is shown a plot 1100 of a two combined optical transition profiles 1120, 1150 of the mixture of different Ba₁₋ₓSrₓFCl: Sm²⁺ nanocrystal materials following irradiation to selectively shift an absorption/emission band to form a spectral hole in the combined optical transition profile to encode digital data according to an illustrative embodiment.

In this example, the mixture was irradiated initially at wavelengths 688.79 nm and 689.48 nm causing spectral holes at these two wavelengths resulting in a combined optical transition profile shown in solid line 1120 having holes 1121, 1122 with two subsequent irradiations or burn fluences at 689.48 nm resulting in the combined optical transition profile shown in solid line 1150 having holes 1151, 1152 with hole 1152 having the same depth as hole 1122. The respective dashed lines 1120a, 1150a show the corresponding different profiles for optical transition profiles 1120, 1150 respectively and the unmodified combined optical transition profile 1010 is also shown for reference purposes.

In this example, the 20% deep hole 1122, 1152 has a hole-width of about 5.8 cm⁻¹ (ie, upper limit of homogenous linewidth of 2.9 cm⁻¹). As can be seen from inspection of plot 1100, the data storage medium, comprising a mixture of different Ba₁₋ₓSrₓFCl: Sm²⁺ nanocrystals, may be used to not only encode digital data by forming a gap or spectral hole at a specific wavelength location but that further data may be stored by the respective depth level of the spectral hole in the combined optical transition profile. Furthermore, the results presented in FIG. 11 correspond to digital data being encoded at room temperature. In the ideal case, the hole-width is twice the homogeneous linewidth for the limit of zero hole-depth. In one example embodiment, a hole-width for relatively deep holes of about 20% of 5.8 cm⁻¹ has been obtained.

Based on the above results, it is expected that a data storage medium comprising a mixture of different Ba₁₋ₓSrₓFCl: Sm²⁺ nanocrystal materials could provide up to 10s if not 100s of bits/point data storage at the diffraction limit which then could potentially allow for data densities approaching the order of magnitude of Tbs/cm² for a 2D configuration and potentially 10s or more Tbs/cm³. As would be appreciated a data storage medium in accordance with the present disclosure will result in significantly increased optical data storage densities.

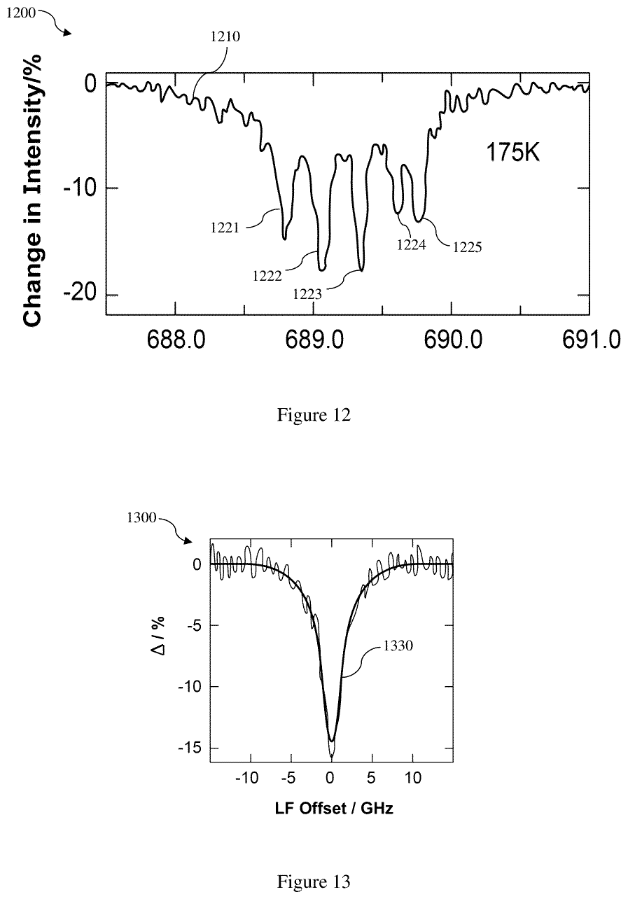

By lowering the temperature, it is possible to reduce the homogeneous linewidths and therefore encode more spectral holes within the combined optical transition profile. Referring now to FIG. 12, there is shown a plot 1200 of the combined optical transition profile 1210 of a data storage medium comprising different nanocrystal materials as previously discussed cooled to 175 K showing multiple holes 1221, 1222, 1223, 1224, 1225 in the ⁵D₀-⁷F₀ transition of Sm²⁺ following irradiation at the respective wavelengths and clearly showing the reduced homogeneous linewidths for each spectral hole as compared to the same material at room temperature as illustrated in FIG. 11.

Referring now to FIG. 13, there is shown a plot 1300 of a spectral hole 1330 in the combined optical transition profile caused by irradiation of the data storage medium comprising different nanocrystal materials as previously discussed at a vacuum wavelength of 688.88 nm where the data storage medium is held at a cryogenic temperature of 30 K displaying a homogeneous hole-width of 3 GHz (0.1 cm⁻¹). These results demonstrate that the number of spectral holes that can be burnt significantly increases at lower temperatures such as obtained by thermoelectric cooling.

Other nanocrystal materials and associated optical transitions that may be used in accordance with the present disclosure include, but are not limited to: Ba₁₋ₓSrₓFBr:Sm²⁺, Ba₁₋ₓSrₓFI:Sm²⁺. In another example, the mixture may comprise different BaₓSr_{y}Ca_{z}FClᵣBrₛIₜ:Sm²⁺ nanocrystal materials where the values of x, y, z, r, s and t are selected from 0 to 1 and subject to the constraints that x+y+z=1 and r+s+t=1 potentially allowing the combined optical transition profile to have a flat region to 200 cm⁻¹.

In one example, a mixture of different nanocrystal materials in accordance with the present disclosure may be formed in a substantially 2D configuration in a nano-crystalline film. In one embodiment, the nano-crystalline film is formed by casting the different nanocrystal materials with any suitable binder such as Kraton™ onto any suitable substrate such as poly(vinyl acetate). In one example, a nano-crystalline film may be formed using the “doctor's blade” technique. In one embodiment, a nano-crystalline film having a thickness of approximately 20 μm was formed by depositing a suspension of different nanocrystal materials with 5% weight of dissolved binder (Kraton™ stabilized with STANN™ in toluene: butyl acetate: methylcyclohexane 9:6:5), on a poly(vinyl acetate) substrate of 100 μm thickness with the mixture then being spread by a doctor's blade to form the resulting nano-crystalline film.

In another example, the different nanocrystal materials in accordance with the present disclosure may be formed in a 3D configuration by volume embedding of the nanocrystal materials into, in one embodiment, low temperature soft glasses (eg, tellurite, lead-silicate, ZBLAN or combinations of these materials). In another example, the nanocrystal materials may be embedded in a polymer media (eg, PMMA, Polystyrene). In another further embodiment, the nanocrystal materials may be embedded in a sol-gel type glass (eg, silica).

As would be appreciated, the composition of the glass or polymer employed will depend on for example optical transmission requirements. For example ZBLAN is more optically transparent at lower wavelengths than polymer for instance—so this material would be potentially indicated where this was the wavelength region of interest. In one example, a surfactant may be used in combination with the nanocrystals so that they disperse on synthesis of the 3D optical medium. In another embodiment, functional groups may be added to the nanocrystal materials to assist with dispersion. In another embodiment, the 3D optical medium may be 3D printed layer-by-layer with a suitable pattern.

Factors that influence the choice of material used to retain and disperse the nanocrystal mixture to form the 3D configuration include, but are not limited to, the materials influence on conversion efficiency, transparency in the UV and visible bands, any background fluorescence and the formation temperature. In one embodiment, low temperature soft glasses may be used to reduce the impact of damage to the nanocrystals on forming the 3D configuration.

In another example embodiment, the mixture comprises nano-sized materials comprising quantum dots. In one example, the nano-sized materials may comprise silver halide based quantum dots. In another example, the nano-sized materials may comprise lead halide based quantum dots.

In embodiments of the present disclosure, the data storage medium may be rewritable in the sense that the spectral holes formed in the combined optical transition profile may be removed by techniques such as laser illumination at the correct wavelength and/or suitable radiation (IR, visible, UV, X-ray) of the data storage medium to remove the encoded information.

A data storage medium formed in accordance with the present disclosure potentially allows for 100 bit/point data storage or more at room temperature that may be implemented in either 2D or 3D configurations representing a significant advance over current optical data storage methodologies. In example embodiments, this is achieved by significantly broadening the inhomogeneous line width of the data storage medium allowing spectral hole burning techniques to be used to encode a greater amount of digital data in the combined optical transition profile of the data storage medium. Furthermore, and in accordance with the present disclosure, spectral holes may be formed at different discrete depth levels allowing digital information to be encoded in the spectral hole itself.

In some cases, a single embodiment may, for succinctness and/or to assist in understanding the scope of the disclosure, combine multiple features. It is to be understood that in such a case, these multiple features may be provided separately (in separate embodiments), or in any other suitable combination. Alternatively, where separate features are described in separate embodiments, these separate features may be combined into a single embodiment unless otherwise stated or implied. This also applies to the claims which can be recombined in any combination. That is a claim may be amended to include a feature defined in any other claim. Further a phrase referring to “at least one of” a list of items refers to any combination of those items, including single members. As an example, “at least one of: a, b, or c” is intended to cover: a, b, c, a-b, a-c, b-c, and a-b-c.

It will be understood that the terms “comprise” and “include” and any of their derivatives (eg, comprises, comprising, includes, including) as used in this specification are to be taken to be inclusive of features to which the term refers, and is not meant to exclude the presence of any additional features unless otherwise stated or implied.

The reference to any prior art in this specification is not, and should not be taken as, an acknowledgement of any form of suggestion that such prior art forms part of the common general knowledge.

It will be appreciated by those skilled in the art that the disclosure is not restricted in its use to the particular application or applications described. Neither is the present disclosure restricted in its preferred embodiment with regard to the particular elements and/or features described or depicted herein. It will be appreciated that the disclosure is not limited to the embodiment or embodiments disclosed, but is capable of numerous rearrangements, modifications and substitutions without departing from the scope as set forth and defined by the following claims.

1. A data storage medium for storing digital data comprising:
a mixture of different nano-sized materials, each of the nano-sized materials having a respective optical transition profile characterizing an optical transition of the nano-sized material and covering a respective wavelength range, wherein a combined optical transition profile of the mixture covers an extended wavelength range as compared to the respective wavelength ranges of the respective optical transition profiles of the different nano-sized materials, and wherein one or more of the different nano-sized materials is photo-reactive to selectively vary a respective absorption/emission band upon irradiation to encode digital data in the combined optical transition profile of the mixture.

2. The data storage medium of claim 1, wherein the respective absorption/emission band is frequency selectively bleached to form a spectral hole in the combined optical transition profile to encode digital data.

3. The data storage medium of claim 2, wherein the spectral hole in the combined optical transition profile is configured to have a predetermined depth level, the predetermined depth level selected from a plurality of depth levels to encode digital data in the spectral hole of the combined optical transition profile.

4. The data storage medium of claim 1, wherein the respective wavelength ranges of the respective optical transition profiles of the different nano-sized materials have substantially the same width.

5. The data storage medium of claim 1, wherein respective peak wavelengths of the respective optical transition profiles of the different nano-sized materials are substantially equally spaced with respect to each other.

6. The data storage medium of claim 1, wherein the combined optical transition profile comprises a substantially flat portion over the extended wavelength range.

7. The data storage medium of claim 1, wherein the mixture is distributed in a substantially two-dimensional (2D) configuration.

8. The data storage medium of claim 1, wherein the mixture is distributed in a substantially three-dimensional (3D) configuration.

9. The data storage medium of claim 1, wherein the different nano-sized materials comprise different BaₓSr_{y}Ca_{z}FClᵣBrₛIₜ: Sm²⁺ nanocrystal materials where the values of x, y, z, r, s and t are selected from 0 to 1 and subject to the constraints that x+y+z=1 and r+s+t=1.

10. The data storage medium of claim 9, wherein the different nano-sized materials comprise different Ba₁₋ₓSrₓFCl: Sm²⁺ nanocrystal materials where x is selected from 0 to 1.

11. The data storage medium of claim 1, wherein the data storage medium is operable to store and read digital data at cryogenic temperatures.

12. The data storage medium of claim 1, wherein the data storage medium is operable to store and read digital data at substantially non-cryogenic temperatures.

13. The data storage medium of claim 12, wherein the data storage medium is operable to store and read digital data at substantially room temperature.

14. A method for storing digital data, comprising:
providing the data storage medium of claim 1;
irradiating the digital storage medium in accordance with the digital data to selectively vary the respective absorption/emission band to encode the digital data.

15. A method for reading stored digital data, comprising:
providing the data storage medium of claim 1; and
determining in accordance with the digital data whether the respective absorption/emission band has been selectively varied to decode the digital data.

16. The method of claim 15, wherein determining whether the respective absorption/emission band has been selectively varied comprises measuring a reflection profile from the data storage medium.

17. The method of claim 15, wherein determining whether the respective absorption/emission band has been selectively varied comprises measuring an absorption profile of the data storage medium.

18. The method of claim 15, wherein determining whether the respective absorption/emission band has been selectively varied comprises measuring an emission profile of the data storage medium.
